(19) United States
(12) Patent Application Publication
(10) Pub. No.: US 2025/0246368 A1
(43) Pub. Date: Jul. 31, 2025

(54) MULTILAYER CERAMIC ELECTRONIC COMPONENT AND ELECTRONIC DEVICE INCLUDING THE SAME

(71) Applicant: SAMSUNG ELECTRONICS CO., LTD., Suwon-si (KR)

(72) Inventor: Inyeol YUN, Suwon-si (KR)

(21) Appl. No.: 18/784,368

(22) Filed: Jul. 25, 2024

(30) Foreign Application Priority Data
Jan. 25, 2024 (KR) 10-2024-0011689

(51) Int. Cl. H01G 4/012; H01G 4/232; H01G 4/30

(52) U.S. Cl. CPC H01G 4/012; H01G 4/232; H01G 4/30

(57) ABSTRACT

Disclosed are multilayer ceramic electronic components and electronic devices including the same. The multilayer ceramic electronic component has a capacitor body including first and second inner electrodes alternately stacked and having first, second, third, and fourth lateral surfaces, and outer electrodes correspondingly disposed on the first to fourth lateral surfaces of the capacitor body. Each of first inner electrodes includes first leadout parts exposed on the first lateral surfaces, and second leadout parts exposed on the second lateral surfaces. Each of second inner electrodes includes third leadout parts exposed at the third lateral surfaces, and fourth leadout parts exposed at the fourth lateral surfaces.

### CROSS-REFERENCE TO RELATED APPLICATION

This U.S. nonprovisional application claims priority under 35 U.S.C § 119 to Korean Patent Application No. 10-2024-0011689 filed on Jan. 25, 2024 in the Korean Intellectual Property Office, the disclosure of which is hereby incorporated by reference in its entirety.

### BACKGROUND

The present inventive concepts relate to a multilayer ceramic electronic component and an electronic device including the same, and more particularly, to a multilayer ceramic capacitor and an electronic device including the same.

With the compactness and high capacity of electronic products, electronic components used in electronic products may also require compactness and high capacity. A multilayer ceramic capacitor (MLCC), one of such electronic components, is mounted on a printed circuit board of various electronic products such as display devices (e.g., liquid crystal displays (LCD) and plasma display panels (PDP)), computers, and smart phones to act to charge or discharge electricity. The multilayer ceramic capacitor may be used as a component for various electronic products because of its compactness and high capacity. The multilayer ceramic capacitor has recently been variously studied to increase reliability in addition to compactness and high capacity.

### SUMMARY

Some embodiments of the present inventive concepts provide a multilayer ceramic electronic component having a compact size and an electronic device including the same.

Some embodiments of the present inventive concepts provide a multilayer ceramic electronic component having improved electrical properties and an electronic device including the same.

The object of the present inventive concepts is not limited to the mentioned above, and other objects which have not been mentioned above will be clearly understood to those skilled in the art from the following description.

According to some embodiments of the present inventive concepts, a multilayer ceramic electronic component includes a capacitor body including a plurality of first inner electrodes and a plurality of second inner electrodes that are alternately stacked, the capacitor body having a plurality of first lateral surfaces that are opposite to each other in a first direction, a plurality of second lateral surfaces that are opposite to each other in a second direction orthogonal to the first direction, a plurality of third lateral surfaces that are opposite to each other in a third direction that intersects the first and second directions, and a plurality of fourth lateral surfaces that are opposite to each other in a fourth direction orthogonal to the third direction; and a plurality of outer electrodes, each of the plurality of outer electrodes on a respective one of the first to fourth lateral surfaces of the capacitor body. Each of the plurality of first inner electrodes includes a plurality of first leadout parts exposed at the first lateral surfaces; and a plurality of second leadout parts exposed at the second lateral surfaces. Each of the plurality of second inner electrodes includes a plurality of third leadout parts exposed at the third lateral surfaces; and a plurality of fourth leadout parts exposed at the fourth lateral surfaces.

According to some embodiments of the present inventive concepts, a multilayer ceramic electronic component includes a capacitor body having at least three first lateral surfaces and a plurality of second lateral surfaces whose number is the same as the number of the first lateral surfaces, wherein each of the second lateral surfaces is between and connects two neighboring ones of the at least three first lateral surfaces; a plurality of first outer electrodes, wherein each of the plurality of first outer electrodes are on a respective one of the at least three first lateral surfaces of the capacitor body and extend in a longitudinal direction; and a plurality of second outer electrodes, wherein each of the plurality of second outer electrodes are on a respective one of the second lateral surfaces of the capacitor body and extend in the longitudinal direction. The capacitor body includes a plurality of first inner electrodes and a plurality of second inner electrodes that are alternately stacked in the longitudinal direction; and a plurality of dielectric layers between the plurality of first inner electrodes and the plurality of second inner electrodes. Each of plurality of first inner electrodes includes a first main part that has a polygonal shape in plan view; and a plurality of first leadout parts that extend toward the plurality of first outer electrodes from the first main part. Each of the plurality of second inner electrodes includes a second main part that has a polygonal shape in plan view; and a plurality of second leadout parts that extend toward the plurality of second outer electrodes from the second main part.

According to some embodiments of the present inventive concepts, an electronic device includes a substrate; and a multilayer ceramic capacitor mounted on the substrate. The multilayer ceramic capacitor includes a capacitor body including a plurality of first inner electrodes and a plurality of second inner electrodes that are stacked in a longitudinal direction to a top surface of the substrate, wherein the capacitor body has a regular octagonal planar shape with a plurality of first lateral surfaces and a plurality of second lateral surfaces that are alternately arranged; a plurality of first outer electrodes, each of the plurality of first outer electrodes on a respective one of the plurality of first lateral surfaces of the capacitor body, the first outer electrodes extending in the longitudinal direction; and a plurality of second outer electrodes, each of the plurality of second outer electrodes on a respective one of the plurality of second lateral surfaces of the capacitor body, the plurality of second outer electrodes extending in the longitudinal direction. Each of the plurality of first inner electrodes and each of the plurality of second inner electrodes includes a main part; and a plurality of leadout parts that extend in different directions from the main part. The plurality of first inner electrodes and the plurality of second inner electrodes may have a same planar shape. The plurality of first inner electrodes and the plurality of second inner electrodes may be rotationally shifted at an angle of about 45 degrees relative to each other.

### BRIEF DESCRIPTION OF DRAWINGS

FIG. 1 is a perspective view showing a multilayer ceramic electronic component according to some embodiments of the present inventive concepts.

FIG. 2 is an exploded perspective view showing a capacitor body of a multilayer ceramic electronic component according to some embodiments of the present inventive concepts.

FIG. 3 is a plan view showing a first inner electrode of a multilayer ceramic electronic component according to some embodiments of the present inventive concepts.

FIG. 4 is a plan view showing a second inner electrode of a multilayer ceramic electronic component according to some embodiments of the present inventive concepts.

FIG. 5 is a plan view showing first and second inner electrodes of a multilayer ceramic electronic component according to some embodiments of the present inventive concepts.

FIG. 6 is a side view showing a multilayer ceramic electronic component according to some embodiments of the present inventive concepts.

FIGS. 7 and 8 are cross-sectional views showing a multilayer ceramic electronic component according to some embodiments of the present inventive concepts.

FIG. 9 is a plan view showing a first inner electrode of a multilayer ceramic electronic component according to some embodiments of the present inventive concepts.

FIG. 10 is a plan view showing a second inner electrode of a multilayer ceramic electronic component according to some embodiments of the present inventive concepts.

FIG. 11 is a plan view showing first and second inner electrodes of a multilayer ceramic electronic component according to some embodiments of the present inventive concepts.

FIG. 12 is a perspective view showing a multilayer ceramic electronic component according to some embodiments of the present inventive concepts.

FIG. 13 is a plan view showing a first inner electrode of a multilayer ceramic electronic component according to some embodiments of the present inventive concepts.

FIG. 14 is a plan view showing a second inner electrode of a multilayer ceramic electronic component according to some embodiments of the present inventive concepts.

FIG. 15 is a plan view showing first and second inner electrodes of a multilayer ceramic electronic component according to some embodiments of the present inventive concepts.

FIG. 16 is a plan view showing a first inner electrode of a multilayer ceramic electronic component according to some embodiments of the present inventive concepts.

FIG. 17 is a plan view showing a second inner electrode of a multilayer ceramic electronic component according to some embodiments of the present inventive concepts.

FIG. 18 is a plan view showing first and second inner electrodes of a multilayer ceramic electronic component according to some embodiments of the present inventive concepts.

FIG. 19 is a cross-sectional view showing an electronic device according to some embodiments of the present inventive concepts.

### DETAILED DESCRIPTION OF EMBODIMENTS

A multilayer ceramic electronic component according to the present inventive concepts will be discussed with reference to the accompanying drawings.

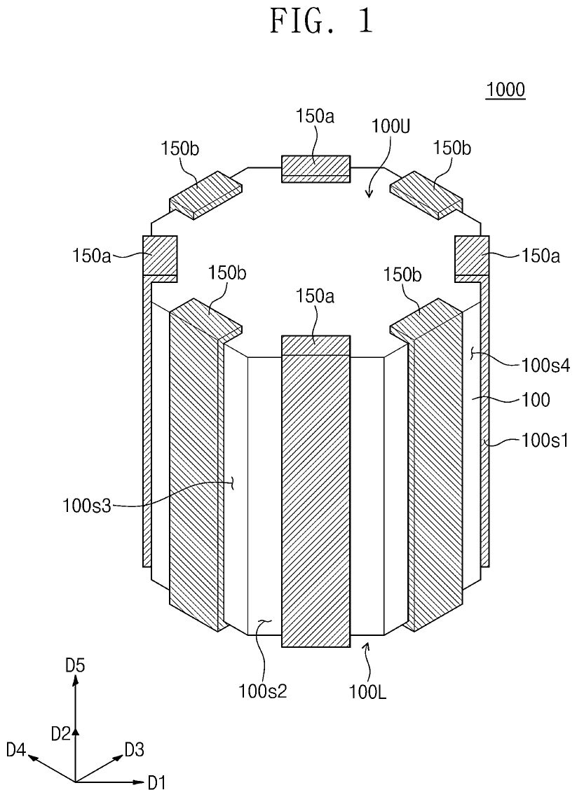

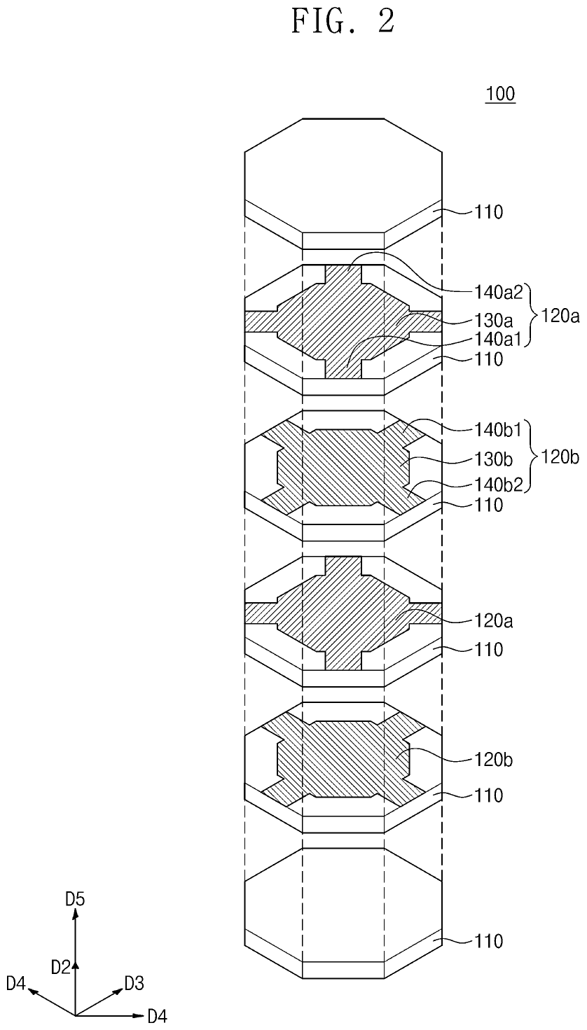

FIG. 1 is a perspective view showing a multilayer ceramic electronic component according to some embodiments of the present inventive concepts. FIG. 2 is an exploded perspective view showing a capacitor body of a multilayer ceramic electronic component according to some embodiments of the present inventive concepts.

Referring to FIGS. 1 and 2, a multilayer ceramic electronic component 1000 may be a multilayer ceramic capacitor. The multilayer ceramic electronic component 1000 may include a capacitor body 100, first outer electrodes 150a, and second outer electrodes 150b.

The capacitor body 100 may be a regular polygonal shape when viewed in plan. An embodiment of the capacitor body 100 will be used to describe in detail below a shape of the capacitor body 100. The capacitor body 100 may have first lateral surfaces 100s1 that are opposite to each other in a first direction D1, second lateral surfaces 100s2 that are opposite to each other in a second direction D2, third lateral surfaces 100s3 that are opposite to each other in a third direction D3, and fourth lateral surfaces 100s4 that are opposite to each other in a fourth direction D4.

The first, second, third, and fourth directions D1, D2, D3, and D4 may be horizontal directions. The first direction D1 and the second direction D2 may be orthogonal to each other. The third direction D3 and the fourth direction D4 may be orthogonal to each other. The third direction D3 and the fourth direction D4 may intersect the first direction D1 and the second direction D2. The third direction D3 and the fourth direction D4 may make an angle of about 45 degrees with the first direction D1 and the second direction D2.

The first, second, third, and fourth lateral surfaces 100s1, 100s2, 100s3, and 100s4 may have the same width in the horizontal direction. For example, the capacitor body 100 may have a regular octagonal shape when viewed in plan. The capacitor body 100 may have a top surface 100U and a bottom surface 100L that are opposite to each other in a fifth direction D5. The fifth direction D5 may be perpendicular to the first, second, third, and fourth directions D1, D2, D3, and D4. For example, the capacitor body 100 may have an octagonal pillar (e.g., column) shape.

The first outer electrodes 150a may be correspondingly disposed on the first lateral surfaces 100s1 and the second lateral surfaces 100s2 of the capacitor body 100. The first outer electrodes 150a may cover portions of the first lateral surfaces 100s1 and portions of the second lateral surfaces 100s2. The first outer electrodes 150a may extend onto the top surface 100U and the bottom surface 100L of the capacitor body 100 to cover portions of the top surface 100U and portions of the bottom surface 100L. The first outer electrodes 150a may surround upper end portions of the capacitor body 100 that are formed between the top surface 100U and the first lateral surfaces 100s1 or the second lateral surfaces 100s2, and may also surround lower end portions of the capacitor body 100 that are formed between the bottom surface 100L and the first lateral surfaces 100s1 or the second lateral surfaces 100s2 (i.e., each of the first outer electrodes 150a may extend around an edge between the top surface 100U and a respective one of the plurality of first lateral surfaces; and each of the first outer electrodes 150a may extend around an edge between the bottom surface 100L and a respective one of the plurality of first lateral surfaces).

The second outer electrodes 150b may be correspondingly disposed on the third lateral surfaces 100s3 and the fourth lateral surfaces 100s4 of the capacitor body 100. The second outer electrodes 150b may cover portions of the third lateral surfaces 100s3 and portions of the fourth lateral surfaces 100s4. The second outer electrodes 150b may extend onto the top surface 100U and the bottom surface 100L of the capacitor body 100 to cover portions of the top surface 100U and portions of the bottom surface 100L. The second outer electrodes 150b may surround upper end portions of the capacitor body 100 that are formed between the top surface 100U and the third lateral surfaces 100s3 or the fourth lateral surfaces 100s4, and may also surround lower end portions of the capacitor body 100 that are formed between the bottom surface 100L and the third lateral surfaces 100s3 or the fourth lateral surfaces 100s4 (i.e., each of the second outer electrodes 150b may extend around an edge between the top surface 100U and a respective one of the plurality of third and fourth lateral surfaces; and each of the second outer electrodes 150b may extend around an edge between the bottom surface 100L and a respective one of the plurality of third and fourth lateral surfaces).

The first and second outer electrodes 150a and 150b may include a conductive material. For example, the first and second outer electrodes 150a and 150b may include nickel (Ni), copper (Cu), palladium (Pd), or any alloy thereof.

The capacitor body 100 may include inner electrodes 120a and 120b and dielectric layers 110 interposed between the inner electrodes 120a and 120b. The inner electrodes 120a and 120b and the dielectric layers 110 may be, for example, alternately stacked along the fifth direction D5. The inner electrodes 120a and 120b may include first inner electrodes 120a and second inner electrodes 120b that are alternately stacked on a lowermost one of the dielectric layers 110. The lowermost one of the dielectric layers 110 may cover an uppermost one of the inner electrodes 120a and 120b. The dielectric layers 110 may include a ceramic material having a high dielectric constant. For example, the dielectric layers 110 may include barium titanate (BaTiO₃) or strontium titanate (SrTiO₃). The inner electrodes 120a and 120b may include a conductive material. For example, the inner electrodes 120a and 120b may include nickel (Ni), copper (Cu), palladium (Pd), or any alloy thereof.

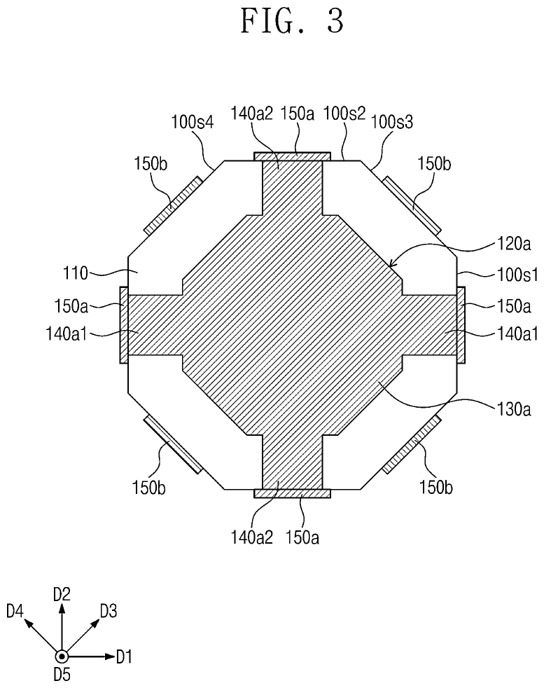

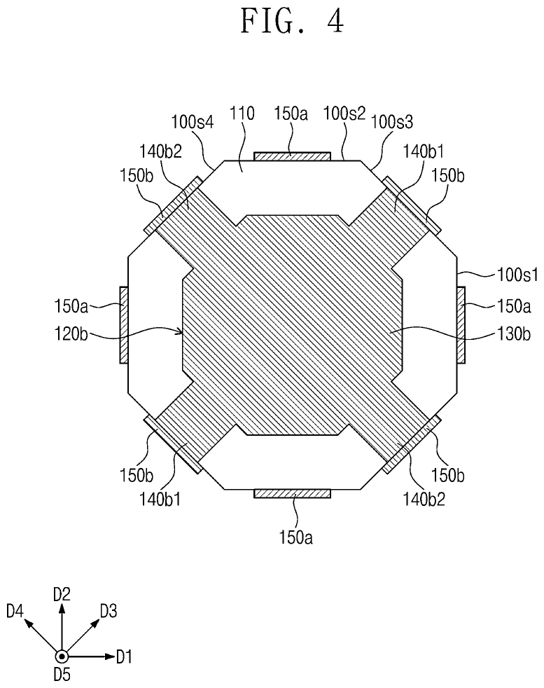

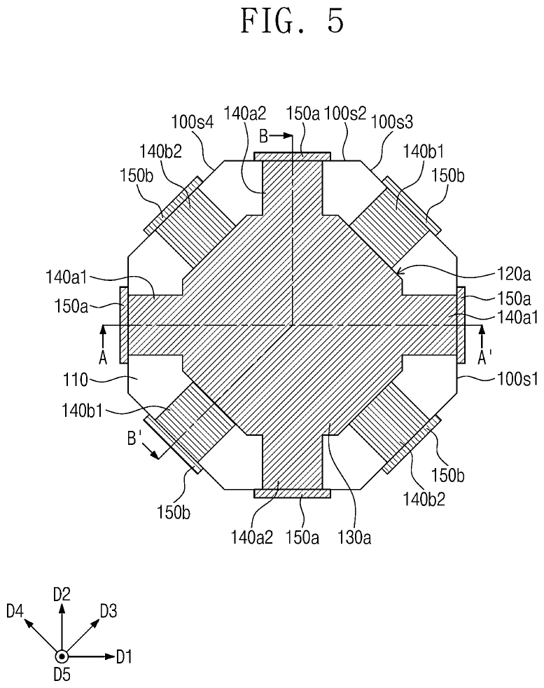

FIG. 3 illustrates a plan view showing a first inner electrode 120a of a multilayer ceramic electronic component according to some embodiments of the present inventive concepts. FIG. 4 illustrates a plan view showing a second inner electrode 120b of a multilayer ceramic electronic component according to some embodiments of the present inventive concepts. FIG. 5 illustrates a plan view of first and second inner electrodes 120a, 120b in a multilayer ceramic electronic component according to some embodiments of the present inventive concepts, showing that one first inner electrode and one second inner electrode overlap each other.

Referring to FIGS. 3 to 5, each of the first inner electrodes 120a may include a first main part 130a, a plurality of first leadout parts 140a1 that extend from the first main part 130a, and a plurality of second leadout parts 140a2 that extend from the first main part 130a.

The first main part 130a may have a planar shape that corresponds to that of the capacitor body 100. For example, the first main part 130a may have a regular octagonal shape when viewed in plan. The first main part 130a may have lateral surfaces directed toward the first direction D1, the second direction D2, the third direction D3, and the fourth direction D4. The planar shape of the first main part 130a may be smaller than that of the capacitor body 100. For example, a width in the horizontal direction of the first main part 130a may be less than a width in the horizontal direction of the capacitor body 100.

When viewed in plan, the first main part 130a may be positioned on a central portion of the capacitor body 100. For example, the first main part 130a may be spaced apart from the first lateral surfaces 100s1, the second lateral surfaces 100s2, the third lateral surfaces 100s3, and the fourth lateral surfaces 100s4 of the capacitor body 100. The same spacing distance may be provided between the first main part 130a and each of the first lateral surfaces 100s1, the second lateral surfaces 100s2, the third lateral surfaces 100s3, and the fourth lateral surfaces 100s4 of the capacitor body 100.

The first leadout parts 140a1 and the second leadout parts 140a2 may extend from the first main part 130a. For example, the first leadout parts 140a1 may correspondingly extend from lateral surfaces in the first direction D1 of the first main part 130a, and the second leadout parts 140a2 may correspondingly extend from lateral surfaces in the second direction D2 of the first main part 130a. The first leadout parts 140a1 may extend toward the first lateral surfaces 100s1 of the capacitor body 100, and the second leadout parts 140a2 may extend toward the second lateral surfaces 100s2 of the capacitor body 100.

The first lateral surfaces 100s1 of the capacitor body 100 may correspondingly expose the first leadout parts 140a1, and the second lateral surfaces 100s2 of the capacitor body 100 may correspondingly expose the second leadout parts 140a2. On the first lateral surfaces 100s1 of the capacitor body 100, the first leadout parts 140a1 may be connected to the first outer electrodes 150a, and on the second lateral surfaces 100s2 of the capacitor body 100, the second leadout parts 140a2 may be connected to the first outer electrodes 150a.

The first leadout parts 140a1 and the second leadout parts 140a2 may each have a linear shape that extends from the first main part 130a. A horizontal width (a width in the second direction D2) of the first leadout part 140a1 may be less than a horizontal width (a width in the second direction D2) of one lateral surface of the first main part 130a, which lateral surface is connected to the first leadout part 140a1. The horizontal width of the first leadout part 140a1 may be less than a horizontal width (a width in the second direction D2) of the first lateral surface 100s1. For example, the horizontal width of the first leadout part 140a1 may be about ⅓ to about ⅔ of the horizontal width of the first lateral surface 100s1. A horizontal width (a width in the first direction D1) of the second leadout part 140a2 may be less than a horizontal width (a width in the first direction D1) of one lateral surface of the first main part 130a, which lateral surface is connected to the second leadout part 140a2. The horizontal width of the second leadout part 140a2 may be less than a horizontal width (a width in the first direction D1) of the second lateral surface 100s2. For example, the horizontal width of the second leadout part 140a2 may be about ⅓ to about ⅔ of the horizontal width of the second lateral surface 100s2.

Each of the second inner electrodes 120b may include a second main part 130b, a plurality of third leadout parts 140b1 that extend from the second main part 130b, and a plurality of fourth leadout parts 140b2 that extend from the second main part 130b.

The second main part 130b may have a planar shape that corresponds to that of the capacitor body 100. For example, the second main part 130b may have a regular octagonal shape when viewed in plan. The second main part 130b may have lateral surfaces directed toward the first direction D1, the second direction D2, the third direction D3, and the fourth direction D4. The planar shape of the second main part 130b may be smaller than that of the capacitor body 100. For example, a width in the horizontal direction of the second main part 130b may be less than the width in the horizontal direction of the capacitor body 100.

When viewed in plan, the second main part 130b may be positioned on the central portion of the capacitor body 100. For example, the second main part 130b may be spaced apart from the first lateral surfaces 100s1, the second lateral surfaces 100s2, the third lateral surfaces 100s3, and the fourth lateral surfaces 100s4 of the capacitor body 100. The same spacing distance may be provided between the second main part 130b and each of the first lateral surfaces 100s1, the second lateral surfaces 100s2, the third lateral surfaces 100s3, and the fourth lateral surfaces 100s4 of the capacitor body 100.

The third leadout parts 140b1 and the fourth leadout parts 140b2 may extend from the second main part 130b. For example, the third leadout parts 140b1 may correspondingly extend from lateral surfaces in the third direction D3 of the second main part 130b, and the fourth leadout parts 140b2 may correspondingly extend from lateral surfaces in the fourth direction D4 from the second main part 130b. The third leadout parts 140b1 may extend toward the third lateral surfaces 100s3 of the capacitor body 100, and the fourth leadout parts 140b2 may extend toward the fourth lateral surfaces 100s4 of the capacitor body 100.

The third lateral surfaces 100s3 of the capacitor body 100 may correspondingly expose the third leadout parts 140b1, and the fourth lateral surfaces 100s4 of the capacitor body 100 may correspondingly expose the fourth leadout parts 140b2. On the third lateral surfaces 100s3 of the capacitor body 100, the third leadout parts 140b1 may be connected to the second outer electrodes 150b, and on the fourth lateral surfaces 100s4 of the capacitor body 100, the fourth leadout parts 140b2 may be connected to the second outer electrodes 150b.

The third leadout parts 140b1 and the fourth leadout parts 140b2 may each have a linear shape that extends from the second main part 130b. A horizontal width (a width in the fourth direction D4) of the third leadout part 140b1 may be less than a horizontal width (a width in the fourth direction D4) of one lateral surface of the second main part 130b, which lateral surface is connected to the third leadout part 140b1. The horizontal width of the third leadout part 140b1 may be less than a horizontal width (a width in the fourth direction D4) of the third lateral surface 100s3. For example, the horizontal width of the third leadout part 140b1 may be about ⅓ to about ⅔ of the horizontal width of the third lateral surface 100s3. A horizontal width (a width in the fourth direction D4) of the fourth leadout part 140b2 may be less than a horizontal width (a width in the fourth direction D4) of one lateral surface of the second main part 130b, which lateral surface is connected to the fourth leadout part 140b2. The horizontal width of the fourth leadout part 140b2 may be less than a horizontal width (a width in the fourth direction D4) of the fourth lateral surface 100s4. For example, the horizontal width of the fourth leadout part 140b2 may be about ⅓ to about ⅔ of the horizontal width of the fourth lateral surface 100s4.

The first inner electrodes 120a and the second inner electrodes 120b may be stacked in the fifth direction D5. The first inner electrodes 120a may have the same planar shape as that of the second inner electrodes 120b, and the first inner electrodes 120a and the second inner electrodes 120b may be rotationally shifted at an angle of about 45 degrees. The first main parts 130a of the first inner electrodes 120a may vertically overlap along the fifth direction D5 with the second main parts 130b of the second inner electrodes 120b.

The first inner electrodes 120a and the second inner electrodes 120b may be buried in the dielectric layers 110. The first inner electrodes 120a and the second inner electrodes 120b may be spaced apart from each other across the dielectric layers 110. A metal-insulator-metal (MIM) structured capacitor may be constituted by one first inner electrode 120a, one second inner electrode 120b adjacent to the one first inner electrodes 120a, and the dielectric layer 110 positioned between the one first inner electrode 120a and the one second inner electrode 120b. A capacitance of the capacitor may depend on an overlapping area of the first inner electrodes 120a and the second inner electrodes 120b, for example, an overlapping area of the first main part 130a and the second main part 130b. Therefore, areas of the first and second main parts 130a and 130b may be adjusted to obtain a capacitance required for the multilayer ceramic electronic component 1000. The dielectric layers 110 may bury the first inner electrodes 120a and the second inner electrodes 120b, and may fill a space between the first leadout parts 140a1 and the second leadout parts 140a2 of the first inner electrodes 120a and a space between the third leadout parts 140b1 and the fourth leadout parts 140b2 of the second inner electrodes 120b.

The first inner electrodes 120a may be connected to the first outer electrodes 150a, and the second inner electrodes 120b may be connected to the second outer electrodes 150b.

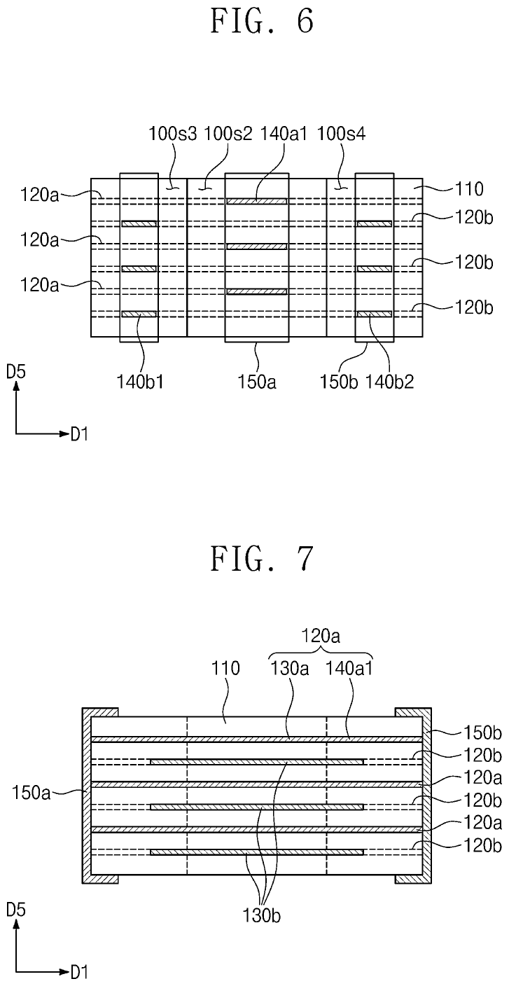

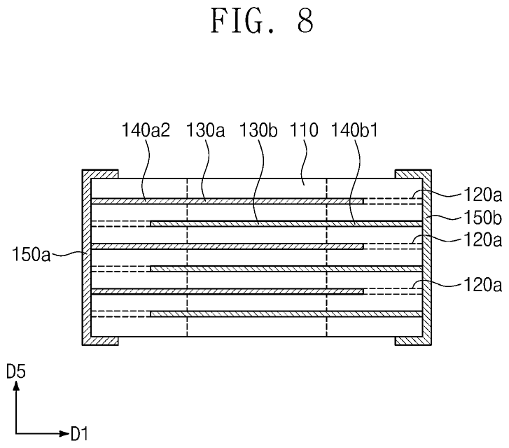

FIG. 6 illustrates a side view of a multilayer ceramic electronic component according to some embodiments of the present inventive concepts, showing the multilayer ceramic electronic component viewed from the front in the second direction D2. FIGS. 7 and 8 illustrate cross-sectional views showing a multilayer ceramic electronic component according to some embodiments of the present inventive concepts. FIG. 7 corresponds to a cross-section taken along line A-A′ of FIG. 5. FIG. 8 corresponds to a cross-section taken along line B-B′ of FIG. 5.

Referring to FIGS. 5 to 8, the first lateral surfaces 100s1 and the second lateral surfaces 100s2 of the capacitor body 100 may expose the first leadout parts 140a1 and the second leadout parts 140a2 (i.e., the first leadout parts 140a1 and the second leadout parts 140a2 are exposed at the first lateral surfaces 100s1 and the second lateral surfaces 100s2, respectively), and the first leadout parts 140a1 and the second leadout parts 140a2 may be connected to the first outer electrodes 150a. The first outer electrodes 150a may extend in the fifth direction D5, and may be connected to the first inner electrodes 120a that are spaced apart from each other.

The third lateral surfaces 100s3 and the fourth lateral surfaces 100s4 of the capacitor body 100 may expose the third leadout parts 140b1 and the fourth leadout parts 140b2 (i.e., the third leadout parts 140b1 and the fourth leadout parts 140b2 are exposed at the third lateral surfaces 100s3 and the fourth lateral surfaces 100s4, respectively), and the third leadout parts 140b1 and the fourth leadout parts 140b2 may be connected to the second outer electrodes 150b. The second outer electrodes 150b may extend in the fifth direction D5, and may be connected to the second inner electrodes 120b that are spaced apart from each other.

The first outer electrodes 150a and the second outer electrodes 150b may be terminals that transfer electrical signals to the capacitor body 100.

According to some embodiments of the present inventive concepts, the multilayer ceramic electronic component 1000 may be configured such that at least three first outer electrodes 150a are provided and at least three second outer electrodes 150b are provided. In this configuration, the first inner electrodes 120a and the second inner electrodes 120b may each have three or more terminals, and thus there may be a reduction in equivalent series inductance (ESL). In addition, each of lateral surfaces of the capacitor body 100 may be provided thereon with only one of the outer electrodes 150a and 150b. Thus, two neighboring ones of the outer electrodes 150a and 150b may be spaced apart from each other at a wide interval, and the capacitor body 100 may be positioned between the outer electrodes 150a and 150b, for example, on a straight pathway that connects to each other two neighboring ones of the outer electrodes 150a and 150b. There may therefore be less interference between the outer electrodes 150a and 150b. In conclusion, the multilayer ceramic electronic component 1000 may have improved electrical properties.

In addition, as the capacitor body 100 is provided in the form of a regular octagon, and as the outer electrodes 150a and 150b are provided on the lateral surfaces 100s1 to 100s4 of the capacitor body 100, the multilayer ceramic electronic component 1000 may be provided to have a symmetric shape when viewed in plan. Therefore, even when the capacitor body 100 has a small size, a sufficient interval may be provided between the outer electrodes 150a and 150b, and the multilayer ceramic electronic component 1000 may become compact-sized.

Moreover, the first inner electrodes 120a and the second inner electrodes 120b may only be rotationally shifted from each other, and may have substantially the same planar shape. Thus, the first inner electrodes 120a and the second inner electrodes 120b may be manufactured through the same process, and the multilayer ceramic electronic component 1000 may be fabricated by a simplified process.

In the embodiments that follow, elements the same as those discussed in the embodiments of FIGS. 1 and 8 are allocated with the same reference numerals, and a repetitive explanation thereof will be omitted or abridged for convenience of description. The following will focus on differences between the embodiments of FIGS. 1 and 8 and other embodiments described below.

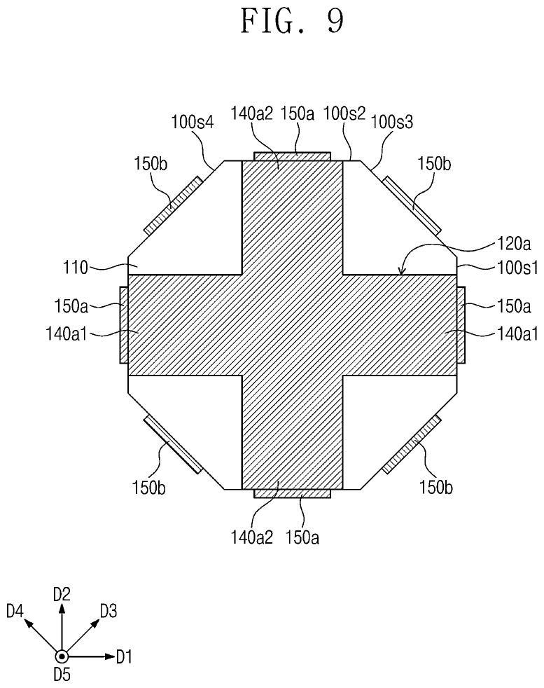

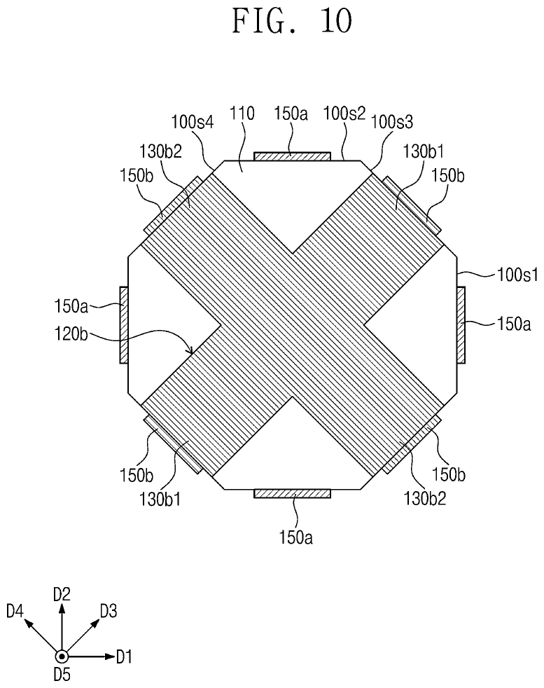

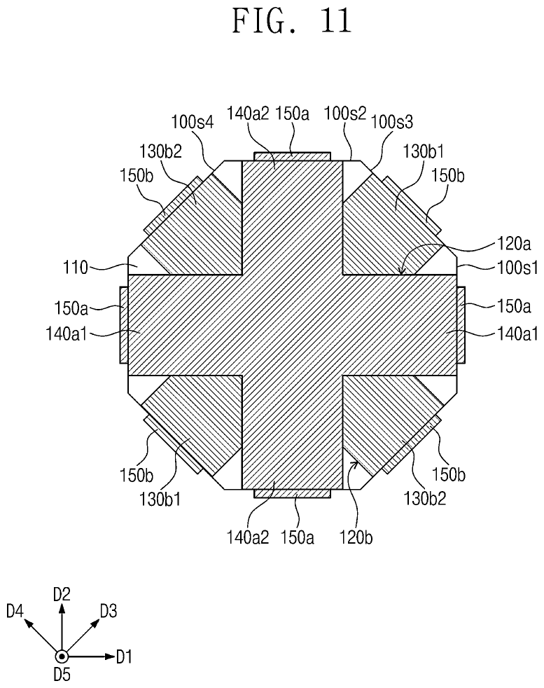

FIG. 9 illustrates a plan view showing a first inner electrode 120a of a multilayer ceramic electronic component according to some embodiments of the present inventive concepts. FIG. 10 illustrates a plan view showing a second inner electrode 120b of a multilayer ceramic electronic component according to some embodiments of the present inventive concepts. FIG. 11 illustrates a plan view of first and second inner electrodes in a multilayer ceramic electronic component according to some embodiments of the present inventive concepts, showing that one first inner electrode and one second inner electrode overlap each other.

FIGS. 1 to 8 depict that the horizontal width of the first leadout part 140a1 and the horizontal width of the second leadout part 140a2 of the first inner electrode 120a are less than the horizontal width of the first main part 130a of the first inner electrode 120a, and that the horizontal width of the third leadout part 140b1 and the horizontal width of the fourth leadout part 140b2 of the second inner electrode 120b are less than the horizontal width of the second main part 130b of the second inner electrode 120b, but the present inventive concepts are not limited thereto.

Referring to FIGS. 9 to 11, the horizontal width of the first leadout part 140a1 and the horizontal width of the second leadout part 140a2 of the first inner electrode 120a may be the same as the horizontal width of the first main part 130a of the first inner electrode 120a. For example, as shown in FIG. 9, the first inner electrodes 120a may each have a cross planar shape obtained when the first leadout part 140a1 extending in the first direction D1 intersects the second leadout part 140a2 extending in the second direction D2.

The second inner electrode 120b may have a planar shape substantially the same as or similar to that of the first inner electrode 120a. The horizontal width of the third leadout part 140b1 and the horizontal width of the fourth leadout part 140b2 of the second inner electrode 120b may be the same as the horizontal width of the second main part 130b of the second inner electrode 120b. For example, as shown in FIG. 10, the second inner electrodes 120b may each have a cross planar shape obtained when the third leadout part 140b1 extending in the third direction D3 intersects the fourth leadout part 140b2 extending in the fourth direction D4.

As shown in FIG. 11, the first inner electrodes 120a and the second inner electrodes 120b may be stacked on the fifth direction D5 (i.e., the first inner electrodes 120a and the second inner electrodes 120b may be stacked on top of each other in the fifth direction D5). The first inner electrodes 120a may have the same planar shape as that of the second inner electrodes 120b, and the first inner electrodes 120a and the second inner electrodes 120b may be rotationally shifted at an angle of about 45 degrees, as illustrated. The first main parts 130a of the first inner electrodes 120a may vertically overlap along the fifth direction D5 with the second main parts 130b of the second inner electrodes 120b.

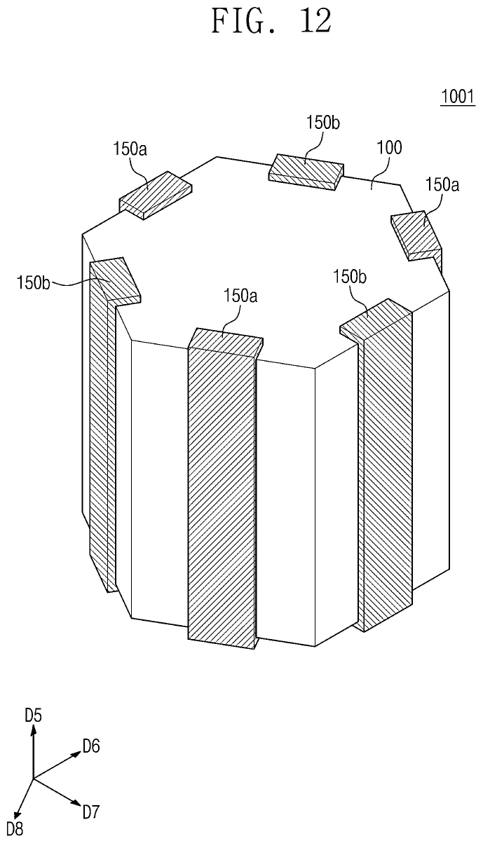

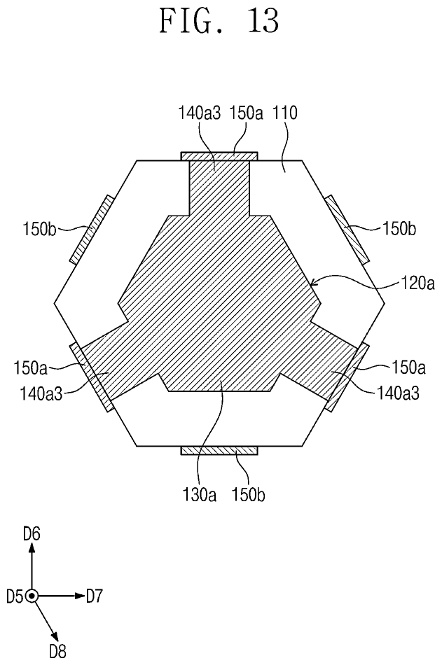

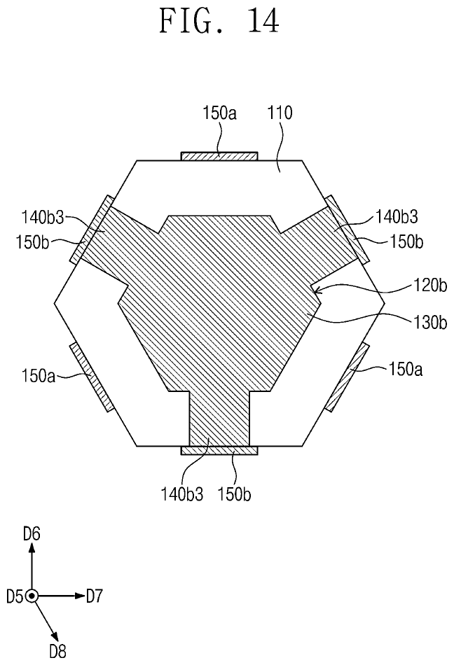

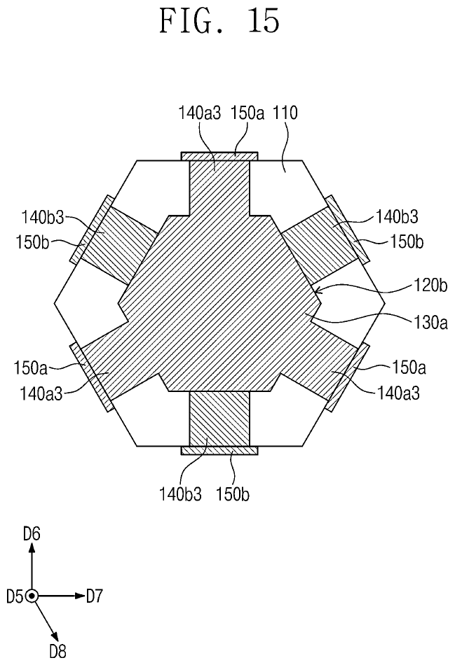

FIG. 12 is a perspective view showing a multilayer ceramic electronic component according to some embodiments of the present inventive concepts. FIG. 13 illustrates a plan view showing a first inner electrode of a multilayer ceramic electronic component according to some embodiments of the present inventive concepts. FIG. 14 illustrates a plan view showing a second inner electrode of a multilayer ceramic electronic component according to some embodiments of the present inventive concepts. FIG. 15 illustrates a plan view showing first and second inner electrodes of a multilayer ceramic electronic component according to some embodiments of the present inventive concepts.

Referring to FIGS. 12 to 15, a multilayer ceramic electronic component 1001 may include a capacitor body 100, first outer electrodes 150a, and second outer electrodes 150b.

The capacitor body 100 may have lateral surfaces that are opposite to each other in a sixth direction D6, lateral surfaces that are opposite to each other in a seventh direction D7, and lateral surfaces that are opposite to each other in an eighth direction D8. The sixth, seventh, and eighth directions D6, D7, and D8 may be horizontal directions. An angle of about 60 degrees may be provided between the sixth, seventh, and eighth directions D6, D7, and D8. The lateral surfaces of the capacitor body 100 may have the same width in the horizontal direction. For example, the capacitor body 100 may have a regular hexagonal shape when viewed in plan. The capacitor body 100 may have a top surface and a bottom surface that are opposite to each other in the fifth direction D5. The fifth direction D5 may be perpendicular to the sixth, seventh, and eighth directions D6, D7, and D8. For example, the capacitor body 100 may have a hexagonal pillar shape.

The first and second outer electrodes 150a and 150b may be correspondingly disposed on the lateral surfaces of the capacitor body 100. In this case, the first and second outer electrodes 150a and 150b may be one-to-one provided on the lateral surfaces of the capacitor body 100 (i.e., one first outer electrode 150a on one lateral surface, one second outer electrode 150b on another lateral surface, etc.), and the first outer electrodes 150a and the second outer electrodes 150b may be alternately placed (i.e., adjacent lateral surfaces have respective different ones of the first and second outer electrodes 150a, 150b). For example, a first outer electrode 150a may be disposed on one of two neighboring lateral surfaces of the capacitor body 100, and a second outer electrode 150b may be disposed on the other of two neighboring lateral surfaces of the capacitor body 100. The first and second outer electrodes 150a and 150b may cover portions of the lateral surfaces of the capacitor body 100. The first and second outer electrodes 150a and 150b may extend onto the top and bottom surfaces of the capacitor body 100 to cover portions of the top and bottom surfaces of the capacitor body 100, as illustrated. The first and second outer electrodes 150a and 150b may surround upper end portions of the capacitor body 100 that are formed between the top surface and the lateral surfaces of the capacitor body 100, and may also surround lower end portions of the capacitor body 100 that are formed between the bottom surface and the lateral surfaces of the capacitor body 100 (i.e., the first and second outer electrodes 150a, 150b extend around an edge between the top surface and a lateral surface of the capacitor body 100, and extend around an edge between the bottom surface and a lateral surface of the capacitor body 100).

The capacitor body 100 may include inner electrodes 120a and 120b and dielectric layers 110 interposed between the inner electrodes 120a and 120b.

Each of the first inner electrodes 120a may include a first main part 130a and a plurality of fifth leadout parts 140a3 that extend from the first main part 130a.

The first main part 130a may have a planar shape that corresponds to that of the capacitor body 100. For example, the first main part 130a may have a regular hexagonal shape in plan view, as illustrated in FIG. 13. The planar shape of the first main part 130a may be smaller than that of the capacitor body 100.

The fifth leadout parts 140a3 may extend from the first main part 130a. For example, the fifth leadout parts 140a3 may correspondingly extend from lateral surfaces of the first main part 130a. In this configuration, the fifth leadout parts 140a3 may be provided on only three of six lateral surfaces of the first main part 130a, as illustrated in FIG. 13. For example, the fifth leadout part 140a3 may be provided on one of two neighboring lateral surfaces of the first main part 130a, and may not be provided on the other of two neighboring lateral surfaces of the first main part 130a. The fifth leadout parts 140a3 may extend onto the lateral surfaces of the capacitor body 100. Each of the lateral surfaces of the capacitor body 100 may expose one of the fifth leadout parts 140a3 (i.e., the fifth leadout parts 140a3 are exposed at the lateral surfaces of the capacitor body 100). On the lateral surfaces of the capacitor body 100, the fifth leadout parts 140a3 may be connected to the first outer electrodes 150a.

Each of the fifth leadout parts 140a3 may have a linear shape that extends from the first main part 130a. A horizontal width of the fifth leadout part 140a3 may be less than that of each lateral surface of the first main part 130a, which lateral surface is connected to the fifth leadout part 140a3. The horizontal width of the fifth leadout part 140a3 may be less than that of each lateral surface of the capacitor body 100. For example, the horizontal width of the fifth leadout part 140a3 may be about ⅓ to about ⅔ of the horizontal width of each lateral surface of the capacitor body 100.

Each of the second inner electrodes 120b may include a second main part 130b and a plurality of sixth leadout parts 140b3 that extend from the second main part 130b.

The second main part 130b may have a planar shape that corresponds to that of the capacitor body 100. For example, the second main part 130b may have a regular hexagonal shape in plan view, as illustrated in FIG. 14. The planar shape of the second main part 130b may be smaller than that of the capacitor body 100.

The sixth leadout parts 140b3 may extend from the second main part 130b. For example, the sixth leadout parts 140b3 may correspondingly extend from lateral surfaces of the second main part 130b. In this configuration, the sixth leadout parts 140b3 may be provided on only three of six lateral surfaces of the second main part 130b, as illustrated in FIG. 14. For example, the sixth leadout part 140b3 may be provided on one of two neighboring lateral surfaces of the second main part 130b, and may not be provided on the other of two neighboring lateral surfaces of the second main part 130b. The sixth leadout parts 140b3 may extend toward the lateral surfaces of the capacitor body 100. Each of the lateral surfaces of the capacitor body 100 may expose one of the sixth leadout parts 140b3 (i.e., the sixth leadout parts 140b3 are exposed at the lateral surfaces). On the lateral surfaces of the capacitor body 100, the sixth leadout parts 140b3 may be connected to the second outer electrodes 150b.

Each of the sixth leadout parts 140b3 may have a linear shape that extends from the second main part 130b. A horizontal width of the sixth leadout part 140b3 may be less than that of each lateral surface of the second main part 130b, which lateral surface is connected to the sixth leadout part 140b3. The horizontal width of the sixth leadout part 140b3 may be less than that of each lateral surface of the capacitor body 100. For example, the horizontal width of the sixth leadout part 140b3 may be about ⅓ to about ⅔ of the horizontal width of each lateral surface of the capacitor body 100.

The first inner electrodes 120a and the second inner electrodes 120b may be stacked in the fifth direction D5 (i.e., the first inner electrodes 120a and the second inner electrodes 120b may be stacked on top of each other in the fifth direction D5). The first inner electrodes 120a may have the same planar shape as that of the second inner electrodes 120b, and the first inner electrodes 120a and the second inner electrodes 120b may be rotationally shifted at an angle of about 60 degrees, as illustrated in FIG. 15. The first main parts 130a of the first inner electrodes 120a may vertically overlap along the fifth direction D5 with the second main parts 130b of the second inner electrodes 120b.

The first inner electrodes 120a and the second inner electrodes 120b may be buried in the dielectric layers 110. The first inner electrodes 120a and the second inner electrodes 120b may be spaced apart from each other across the dielectric layers 110. A metal-insulator-metal (MIM) structured capacitor may be constituted by one first inner electrode 120a, one second inner electrode 120b adjacent to the one first inner electrodes 120a, and the dielectric layer 110 positioned between the one first inner electrode 120a and the one second inner electrode 120b.

The first inner electrodes 120a may be connected to the first outer electrodes 150a, and the second inner electrodes 120b may be connected to the second outer electrodes 150b.

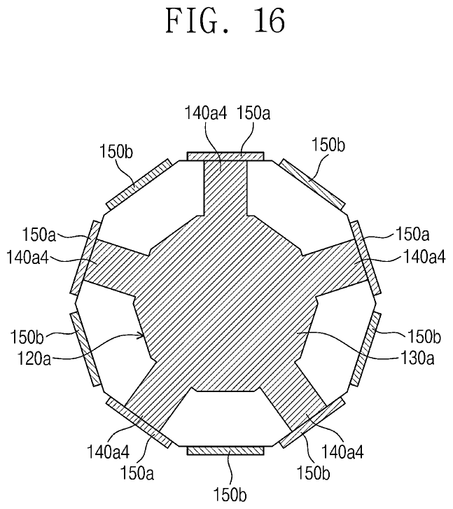

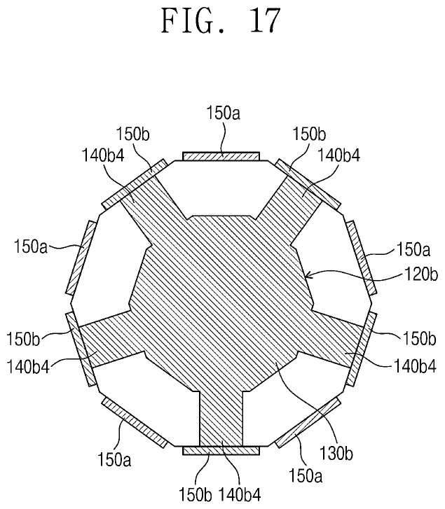

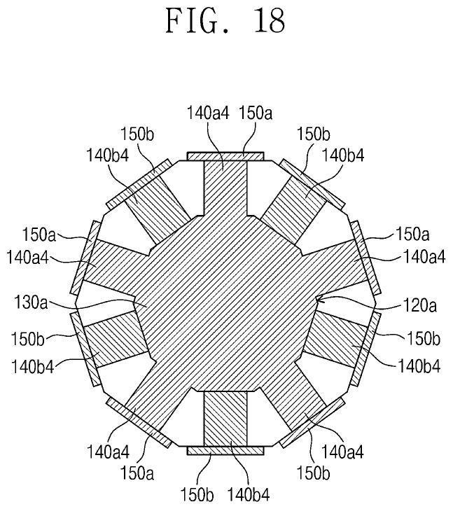

FIG. 16 is a plan view showing a first inner electrode of a multilayer ceramic electronic component according to some embodiments of the present inventive concepts. FIG. 17 is a plan view showing a second inner electrode of a multilayer ceramic electronic component according to some embodiments of the present inventive concepts. FIG. 18 is a plan view showing first and second inner electrodes of a multilayer ceramic electronic component according to some embodiments of the present inventive concepts.

Referring to FIGS. 16 to 18, a multilayer ceramic electronic component 1001 may include a capacitor body 100, first outer electrodes 150a, and second outer electrodes 150b.

The capacitor body 100 may have a regular decagonal shape when viewed in plan. The lateral surfaces of the capacitor body 100 may have the same width in the horizontal direction. The capacitor body 100 may have a top surface and a bottom surface that are opposite to each other in the fifth direction D5. For example, the capacitor body 100 may have a decagonal pillar shape.

The first and second outer electrodes 150a and 150b may be correspondingly disposed on the lateral surfaces of the capacitor body 100, as illustrated. In this case, the outer electrodes 150a and 150b may be one-to-one provided on the lateral surfaces of the capacitor body 100 (i.e., one first outer electrode 150a on one later surface, one second outer electrode 150b on another lateral surface, etc.), and the first outer electrodes 150a and the second outer electrodes 150b may be alternately placed (i.e., adjacent lateral surfaces have respective different ones of the first and second electrodes 150a, 150b). For example, the first outer electrode 150a may be disposed on one of two neighboring lateral surfaces of the capacitor body 100, and the second outer electrode 150b may be disposed on the other of two neighboring lateral surfaces of the capacitor body 100. The first and second outer electrodes 150a and 150b may cover portions of the lateral surfaces of the capacitor body 100. The first and second outer electrodes 150a and 150b may extend onto the top and bottom surfaces of the capacitor body 100 to cover portions of the top and bottom surfaces of the capacitor body 100, as illustrated. The first and second outer electrodes 150a and 150b may surround upper end portions of the capacitor body 100 that are formed between the top surface and the lateral surfaces of the capacitor body 100, and may also surround lower end portions of the capacitor body 100 that are formed between the bottom surface and the lateral surfaces of the capacitor body 100 (i.e., the first and second outer electrodes 150a, 150b extend around an edge between the top surface and the lateral surfaces of the capacitor body 100, and extend around an edge between the bottom surface and the lateral surfaces of the capacitor body 100).

The capacitor body 100 may include inner electrodes 120a and 120b and dielectric layers 110 interposed between the inner electrodes 120a and 120b.

Each of the first inner electrodes 120a may include a first main part 130a and a plurality of seventh leadout parts 140a4 that extend from the first main part 130a.

The first main part 130a may have a planar shape that corresponds to that of the capacitor body 100. For example, the first main part 130a may have a regular decagonal shape when viewed in plan. The planar shape of the first main part 130a may be smaller than that of the capacitor body 100.

The seventh leadout parts 140a4 may extend from the first main part 130a. For example, the seventh leadout parts 140a4 may correspondingly extend from lateral surfaces of the first main part 130a. In this configuration, the seventh leadout parts 140a4 may be provided on only five of ten lateral surfaces of the first main part 130a, as illustrated in FIG. 16. For example, the seventh leadout part 140a4 may be provided on one of two neighboring lateral surfaces of the first main part 130a, and may not be provided on the other of two neighboring lateral surfaces of the first main part 130a. The seventh leadout parts 140a4 may extend onto the lateral surfaces of the capacitor body 100. Each of the lateral surfaces of the capacitor body 100 may expose one seventh leadout part 140a4 (i.e., the seventh leadout parts 140a4 are exposed at respective lateral surfaces of the capacitor body 100). On the lateral surfaces of the capacitor body 100, the seventh leadout parts 140a4 may be connected to the first outer electrodes 150a.

Each of the seventh leadout parts 140a4 may have a linear shape that extends from the first main part 130a. A horizontal width of the seventh leadout part 140a4 may be less than that of each lateral surface of the first main part 130a, which lateral surface is connected to the seventh leadout part 140a4. The horizontal width of the seventh leadout part 140a4 may be less than that of each lateral surface of the capacitor body 100. For example, the horizontal width of the seventh leadout part 140a4 may be about ⅓ to about ⅔ of the horizontal width of each lateral surface of the capacitor body 100.

Each of the second inner electrodes 120b may include a second main part 130b and a plurality of eighth leadout parts 140b4 that extend from the second main part 130b.

The second main part 130b may have a planar shape that corresponds to that of the capacitor body 100. For example, the second main part 130b may have a regular decagonal shape in plan view, as illustrated in FIG. 17. The planar shape of the second main part 130b may be smaller than that of the capacitor body 100.

The eighth leadout parts 140b4 may extend from the second main part 130b. For example, the eighth leadout parts 140b4 may correspondingly extend from lateral surfaces of the second main part 130b. In this configuration, the eighth leadout parts 140b4 may be provided on only five of ten lateral surfaces of the second main part 130b, as illustrated in FIG. 17. For example, the eighth leadout part 140b4 may be provided on one of two neighboring lateral surfaces of the second main part 130b, and may not be provided on the other of two neighboring lateral surfaces of the second main part 130b. The eighth leadout parts 140b4 may extend toward the lateral surfaces of the capacitor body 100. Each of the lateral surfaces of the capacitor body 100 may expose one of the eighth leadout parts 140b4 (i.e., the eighth leadout parts 140b4 are exposed at respective lateral surfaces of the capacitor body 100). On the lateral surfaces of the capacitor body 100, the eighth leadout parts 140b4 may be connected to the second outer electrodes 150b.

Each of the eighth leadout parts 140b4 may have a linear shape that extends from the second main part 130b. A horizontal width of the eighth leadout part 140b4 may be less than that of each lateral surface of the second main part 130b, which lateral surface is connected to the eighth leadout part 140b4. The horizontal width of the eighth leadout part 140b4 may be less than that of each lateral surface of the capacitor body 100. For example, the horizontal width of the eighth leadout part 140b4 may be about ⅓ to about ⅔ of the horizontal width of each lateral surface of the capacitor body 100.

The first inner electrodes 120a and the second inner electrodes 120b may be stacked in the fifth direction D5 (i.e., the first inner electrodes 120a and the second inner electrodes 120b may be stacked on top of each other in the fifth direction D5). The first inner electrodes 120a may have the same planar shape as that of the second inner electrodes 120b, and the first inner electrodes 120a and the second inner electrodes 120b may be rotationally shifted at an angle of about 36 degrees, as illustrated in FIG. 18. The first main parts 130a of the first inner electrodes 120a may vertically overlap along the fifth direction D5 with the second main parts 130b of the second inner electrodes 120b.

The first inner electrodes 120a and the second inner electrodes 120b may be buried in the dielectric layers 110. The first inner electrodes 120a and the second inner electrodes 120b may be spaced apart from each other across the dielectric layers 110. A metal-insulator-metal (MIM) structured capacitor may be constituted by one first inner electrode 120a, one second inner electrode 120b adjacent to the one first inner electrodes 120a, and the dielectric layer 110 positioned between the one first inner electrode 120a and the one second inner electrode 120b.

The first inner electrodes 120a may be connected to the first outer electrodes 150a, and the second inner electrodes 120b may be connected to the second outer electrodes 150b.

The embodiments of FIGS. 1 to 18 explain that a plan view of the capacitor body 100 has a regular octagonal planar shape, a regular hexagonal planar shape, or a regular decagonal planar shape, but the present inventive concepts are not limited thereto. The capacitor body 100 may have a regular n-sided polygonal shape when viewed in plan, and n may be equal to or greater than 4.

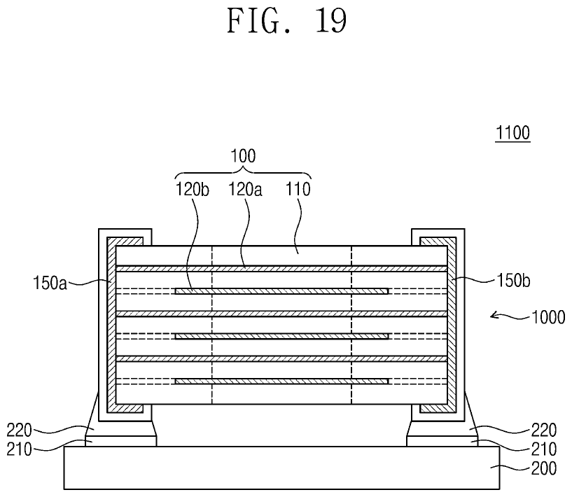

FIG. 19 is a cross-sectional view showing a semiconductor device according to some embodiments of the present inventive concepts.

Referring to FIG. 19, an electronic device 1100 may include a substrate 200 and a multilayer ceramic capacitor 1000 mounted on the substrate 200. The substrate 200 may have substrate pads 210 provided on a top surface of the substrate 200. The substrate pads 210 may include a conductive material. The multilayer ceramic capacitor 1000 may be the multilayer ceramic electronic component 1000 or 1001 discussed with FIGS. 1 to 18. The multilayer ceramic capacitor 1000 may be mounted on the substrate 200 to allow the bottom surface 100L of the capacitor body 100 of FIG. 1 to face the top surface of the substrate 200. The first and second outer electrodes 150a and 150b of the multilayer ceramic capacitor 1000 may be correspondingly disposed on the substrate pads 210. A solder 220 may be disposed on one of the first and second outer electrodes 150a and 150b and one of the substrate pads 210. The solder 220 may partially cover an outer lateral surface of each of the first and second outer electrodes 150a and 150b. The solder 220 may include tin (Sn), lead (Pb), silver (Ag), copper (Cu), gold (Au), and any alloy thereof. The solder 220 may further include a conductive polymer.

A multilayer ceramic electronic component according to some embodiments of the present inventive concepts may be provided with at least three first outer electrodes and at least three second outer electrodes. In this configuration, each of first and second inner electrodes may have three or more terminals, and thus there may be a reduction in equivalent series inductance (ESL). The outer electrodes may be one-to-one provided on lateral surfaces of a capacitor body. Two neighboring ones of the outer electrodes may be spaced apart from each other at a wide interval, and the capacitor body may be positioned between the outer electrodes. There may thus be less interference between the outer electrodes. Accordingly, a multilayer ceramic electronic component may be provided which have improved electrical properties.

In addition, as the capacitor body is provided in the form of a polygon, and as the outer electrodes are correspondingly provided on the lateral surfaces of the capacitor body, the multilayer ceramic electronic component may be provided to have a symmetric shape when viewed in plan. Therefore, even when the capacitor body has a small size, a sufficient interval may be provided between the outer electrodes, and the multilayer ceramic electronic component may become compact-sized.

Moreover, the first inner electrodes and the second inner electrodes may only be rotationally shifted from each other, and may have substantially the same planar shape. Thus, the first inner electrodes and the second inner electrodes may be manufactured through the same process, and the multilayer ceramic electronic component may be fabricated by a simplified process.

Although the present invention has been described in connection with some embodiments of the present inventive concepts illustrated in the accompanying drawings, it will be understood by one of ordinary skill in the art that variations in form and detail may be made therein without departing from the present inventive concepts. The above disclosed embodiments should thus be considered illustrative and not restrictive.

1. A multilayer ceramic electronic component, comprising:
a capacitor body comprising a plurality of first inner electrodes and a plurality of second inner electrodes that are alternately stacked, the capacitor body comprising a plurality of first lateral surfaces that are opposite each other in a first direction, a plurality of second lateral surfaces that are opposite each other in a second direction orthogonal to the first direction, a plurality of third lateral surfaces that are opposite each other in a third direction that intersects the first and second directions, and a plurality of fourth lateral surfaces that are opposite each other in a fourth direction orthogonal to the third direction; and
a plurality of outer electrodes, each of the plurality of outer electrodes on a respective one of the first to fourth lateral surfaces of the capacitor body,
wherein each of the plurality of first inner electrodes comprises:
a plurality of first leadout parts, each of the plurality of first leadout parts exposed at a respective one of the plurality of first lateral surfaces; and
a plurality of second leadout parts, each of the plurality of second leadout parts exposed at a respective one of the plurality of second lateral surfaces, and
wherein each of the plurality of second inner electrodes comprises:
a plurality of third leadout parts, each of the plurality of third leadout parts exposed at a respective one of the plurality of third lateral surfaces; and
a plurality of fourth leadout parts, each of the plurality of fourth leadout parts exposed at a respective one of the plurality of fourth lateral surfaces.

2. The multilayer ceramic electronic component of claim 1, wherein
each of the plurality of first inner electrodes further comprises a first main part,
each of the plurality of first leadout parts extends toward one of the plurality of first lateral surfaces from the first main part,
each of the plurality of second leadout parts extends toward one of the plurality of second lateral surfaces from the first main part,
each of the plurality of second inner electrodes further comprises a second main part,
each of the plurality of third leadout parts extends toward one of the plurality of third lateral surfaces from the second main part, and
each of the plurality of fourth leadout parts extends toward one of the plurality of fourth lateral surfaces from the second main part.

3. The multilayer ceramic electronic component of claim 2, wherein, in plan view, the first main part and the second main part have an octagonal shape.

4. The multilayer ceramic electronic component of claim 3, wherein
a horizontal width of each of the plurality of first leadout parts and each of the plurality of second leadout parts is the same as or less than a horizontal width of a lateral surface of the first main part, and
a horizontal width of each of the plurality of third leadout parts and each of the plurality of fourth leadout parts is the same as or less than a horizontal width of a lateral surface of the second main part.

5. The multilayer ceramic electronic component of claim 2, wherein
each of the plurality of first leadout parts and each of the plurality of second leadout parts has a linear shape that extends from the first main part, and
each of the plurality of third leadout parts and each of the plurality of fourth leadout parts has a linear shape that extends from the second main part.

6. The multilayer ceramic electronic component of claim 1, wherein
each of the plurality of first inner electrodes has a cross planar shape formed by the plurality of first leadout parts and the plurality of second leadout parts, and
each of the plurality of second inner electrodes has a cross planar shape formed by the plurality of third leadout parts and the plurality of fourth leadout parts.

7. The multilayer ceramic electronic component of claim 1, wherein the plurality of outer electrodes comprise:
a plurality of first outer electrodes that extend in a fifth direction on respective ones of the plurality of first lateral surfaces of the capacitor body;
a plurality of second outer electrodes that extend in the fifth direction on respective ones of the plurality of second lateral surfaces of the capacitor body;
a plurality of third outer electrodes that extend in the fifth direction on respective ones of the plurality of third lateral surfaces of the capacitor body; and
a plurality of fourth outer electrodes that extend in the fifth direction on respective ones of the plurality of fourth lateral surfaces of the capacitor body.

8. The multilayer ceramic electronic component of claim 7, wherein
the plurality of first leadout parts of the plurality of first inner electrodes are connected to the plurality of first outer electrodes,
the plurality of second leadout parts of the plurality of first inner electrodes are connected to the plurality of second outer electrodes,
the plurality of third leadout parts of the plurality of second inner electrodes are connected to the plurality of third outer electrodes, and
the plurality of fourth leadout parts of the plurality of second inner electrodes are connected to the plurality of fourth outer electrodes.

9. The multilayer ceramic electronic component of claim 1, wherein
the capacitor body has an octagonal shape in plan view, and
the plurality of first lateral surfaces, the plurality of second lateral surfaces, the plurality of third lateral surfaces, and the plurality of fourth lateral surfaces have a same horizontal width.

10. The multilayer ceramic electronic component of claim 1, wherein a horizontal width of each of the plurality of first leadout parts, each of the plurality of second leadout parts, each of the plurality of third leadout parts, and each of the plurality of fourth leadout parts is about ⅓ to about ⅔ of a horizontal width of each of the plurality of first lateral surfaces, each of the plurality of second lateral surfaces, each of the plurality of third lateral surfaces, and each of the plurality of the fourth lateral surfaces.

11. The multilayer ceramic electronic component of claim 1, wherein the third direction forms an angle of about 45 degrees with the first and second directions.

12. The multilayer ceramic electronic component of claim 1, wherein
the capacitor body further comprises a plurality of dielectric layers between the plurality of first inner electrodes and the plurality of second inner electrodes, and
the plurality of dielectric layers fill a space between the plurality of first leadout parts and the plurality of second leadout parts and a space between the plurality of third leadout parts and the plurality of fourth leadout parts.

13. The multilayer ceramic electronic component of claim 1, wherein
the plurality of first inner electrodes and the plurality of second inner electrodes have a same planar shape, and
the plurality of first inner electrodes and the plurality of second inner electrodes are rotationally shifted at an angle of about 45 degrees relative to each other.

14. A multilayer ceramic electronic component, comprising:
a capacitor body comprising at least three first lateral surfaces and a plurality of second lateral surfaces equal in number to the at least three first lateral surfaces, wherein each of the plurality of second lateral surfaces is between and connects two neighboring ones of the at least three first lateral surfaces;
a plurality of first outer electrodes, wherein each of the plurality of first outer electrodes are on a respective one of the at least three first lateral surfaces of the capacitor body, and wherein each of the plurality of first outer electrodes extends in a longitudinal direction of the capacitor body; and
a plurality of second outer electrodes, wherein each of the plurality of second outer electrodes are on a respective one of the plurality of second lateral surfaces of the capacitor body, and wherein each of the plurality of second outer electrodes extend in the longitudinal direction,
wherein the capacitor body comprises:
a plurality of first inner electrodes and a plurality of second inner electrodes that are alternately stacked in the longitudinal direction; and
a plurality of dielectric layers between the plurality of first inner electrodes and the plurality of second inner electrodes,
wherein each of plurality of first inner electrodes comprises:
a first main part that has a polygonal shape in plan view; and
a plurality of first leadout parts that extend toward the plurality of first outer electrodes from the first main part, and
wherein each of plurality of second inner electrodes comprises:
a second main part that has a polygonal shape in plan view; and
a plurality of second leadout parts that extend toward the plurality of second outer electrodes from the second main part.

15. The multilayer ceramic electronic component of claim 14, wherein
the capacitor body comprises four first lateral surfaces and four second lateral surfaces, and
the capacitor body has an octagonal shape in plan view.

16. The multilayer ceramic electronic component of claim 15, wherein each of the plurality of first main parts and the plurality of second main parts has an octagonal planar shape in plan view.

17. The multilayer ceramic electronic component of claim 15, wherein
the capacitor body has an octagonal shape in plan view, and
the at least three first lateral surfaces and the plurality of second lateral surfaces have a same horizontal width.

18-23. (canceled)

24. An electronic device, comprising:
a substrate; and
a multilayer ceramic capacitor mounted on the substrate,
wherein the multilayer ceramic capacitor comprises:
a capacitor body comprising a plurality of first inner electrodes and a plurality of second inner electrodes that are stacked in a longitudinal direction to a top surface of the substrate, wherein the capacitor body has an octagonal planar shape with a plurality of first lateral surfaces and a plurality of second lateral surfaces that are alternately arranged;
a plurality of first outer electrodes, each of the plurality of first outer electrodes on a respective one of the plurality of first lateral surfaces of the capacitor body, the plurality of first outer electrodes extending in the longitudinal direction; and
a plurality of second outer electrodes, each of the plurality of second outer electrodes on a respective one of the plurality of second lateral surfaces of the capacitor body, the plurality of second outer electrodes extending in the longitudinal direction,
wherein each of the plurality of first inner electrodes and each of the plurality of second inner electrodes comprises:
a main part; and
a plurality of leadout parts that extend in different directions from the main part,
wherein the plurality of first inner electrodes and the plurality of second inner electrodes have a same planar shape, and
wherein the plurality of first inner electrodes and the plurality of second inner electrodes are rotationally shifted at an angle of about 45 degrees relative to each other.

25. The electronic device of claim 24, wherein
the plurality of leadout parts of each of the plurality of first inner electrodes extend toward the plurality of first lateral surfaces from the main part and are connected to the plurality of first outer electrodes, and
the plurality of leadout parts of each of the plurality of second inner electrodes extend toward the plurality of second lateral surfaces from the main part and are connected to the plurality of second outer electrodes.

26. The electronic device of claim 25, wherein the main part of each of the plurality of first inner electrodes and each of the plurality of second inner electrodes has an octagonal planar shape.

27-31. (canceled)
